(19) United States
(12) Patent Application Publication
(10) Pub. No.: US 2011/0318932 A1
(43) Pub. Date: Dec. 29, 2011

(54) Pyrolysis Methods, Catalysts, and Apparatuses for Treating and/or Detecting Gas Contaminants

(75) Inventors: Lyle E. MONSON, Schaumburg, IL (US); Dean E. RENDE, Arlington Heights, IL (US)

(73) Assignee: UOP LLC, Des Plaines, IL (US)

(21) Appl. No.: 12/824,873

(22) Filed: Jun. 28, 2010

(51) Int. Cl. B01D 53/68; H01L 21/461

(52) U.S. Cl. 438/706; 423/240 R; 423/240 S; 422/173; 257/E21.219

(57) ABSTRACT

Processes for treating gas streams contaminated with fluorine-containing compounds, in addition to apparatuses for such treatment processes that may also be used to monitor the emission of these compounds, are disclosed. In the processes and apparatuses, catalytic conversion (pyrolysis) one or more fluorine-containing contaminants (e.g., perfluorocarbon) in the gas stream is carried out using a catalyst comprising tungstated zirconia or sulfated zirconia. The catalysts exhibit exceptional responsiveness, recovery, and/or activity, compared to conventional catalysts, for this purpose.

### FIELD OF THE INVENTION

The present invention relates to methods, catalysts, and apparatuses for treating gas streams contaminated with one or more fluorine-containing compounds, including perfluorocarbons and/or hydrofluorocarbons. Representative processes comprise contacting the gas stream with a catalyst comprising tungstated zirconia or sulfated zirconia to convert at least a portion of the fluorinated compounds by pyrolysis.

### DESCRIPTION OF RELATED ART

Fluorine-containing compounds including perfluorinated hydrocarbons (i.e., perfluorocarbon compounds) are used extensively in the manufacture of semiconductor materials, and particularly for dry chemical etching and chamber cleaning processes. Perfluorinated compounds in general refer to compounds composed of nitrogen, carbon, and/or sulfur atoms, or mixtures of these atoms, and fluorine atoms but not hydrogen atoms. Other fluorine-containing compounds that may be utilized and/or emitted in semiconductor production have both hydrogen and fluorine atoms. Hydrofluorocarbons, for example, refer to hydrocarbons having one or more carbon atoms substituted with fluorine, and these are often generated as semiconductor manufacturing byproducts. Other uses for perfluorinated compounds and hydrofluorocarbons include polymer blowing agents and refrigerants.

Since the global warming potential of these compounds is thought to be many times greater than that of CO₂ the desire for economical technologies to control emissions of fluorinated compounds is significant. Catalytic technologies are conventionally used as a final control of industrial emissions. Catalytic conversion of fluorine-containing compounds generally involves passing a gas stream contaminated with these compounds over the active catalyst in the presence of oxygen and/or water at an elevated temperature, in order to convert (i.e., pyrolyze) the fluorine-containing pollutant compounds to carbon dioxide, water, and hydrogen fluoride (HF) in the treated gas stream or effluent. Catalytic conversion offers substantial advantages over thermal incineration for control of fluorine-containing compound emissions. Primarily, the incorporation of a catalyst to accelerate the reaction rate allows the decomposition reaction temperature to be reduced by several hundred degrees Celsius, relative to non-catalytic (thermal) processes. The temperature reduction results in energy/operating cost savings, in addition to lower capital costs, a small foot print of resulting abatement unit, a more controllable process, and the elimination of thermal nitrogen oxide (NOₓ) emissions.

The performance of any catalytic treatment process is largely a function of the particular catalyst used. An important consideration is the ability of the catalyst to withstand the reaction environment that results from the catalytic decomposition or destruction of perfluorocarbons, hydrofluorocarbons, and/or other fluorine-containing contaminants to highly corrosive products such as HF, F₂, and COF₂. Many catalytic materials fail to maintain their integrity in this reaction environment, due to fluorine attack, for a significant duration. The instability of such catalysts causes a decrease in contaminant conversion after only a few days of operation. Titania (TiO₂) catalyst supports, for example, are known to convert readily to TiF₄, resulting a loss of both surface area and catalytic activity over a commercially relevant period of operation. A similar phenomenon has been observed with respect to the conversion of alumina supports to AlF₃, despite the fact that alumina is considered very thermally stable and non-reactive (refractory) as a catalyst support in a large number of catalytic reactions.

There is consequently a need in the art for catalyst compositions that are stable in the presence of corrosive compounds including the catalytic decomposition products of fluorine-containing compounds such as perfluorocarbons. When used in toxic gas monitoring and/or treatment apparatuses, such catalyst compositions ideally exhibit not only a long life but also a favorable response and recovery times, in addition to minimal adsorption/deposition of fluorine-containing residues on the catalyst over the course of operation.

### SUMMARY OF THE INVENTION

The present invention relates to processes for treating gas streams contaminated with fluorine-containing compounds, in addition to apparatuses for such treatment processes that may also be used to monitor the emission of these compounds. Monitoring, for example, may be achieved through the detection of hydrogen fluoride generated from the catalytic decomposition of perfluorinated compounds and/or other fluorine-containing compounds such as those typically used in semiconductor manufacturing and particularly in dry etching operations. Representative apparatuses have a catalyst-containing quartz tube that acts as a reactor for pyrolyzing fluorine-containing compounds in the presence of water to carbon dioxide (CO₂) and hydrogen fluoride (HF).

In particular, aspects of the invention are associated with the discovery of catalysts that are highly stable in the reaction environment described above, containing hydrogen fluoride and possibly other highly corrosive pyrolysis reaction products, such that the catalysts are suitable for commercial use over a number of years. Moreover, the catalysts are highly active and thereby demonstrate an effective fluorine-containing compound conversion level (e.g., at least about 90%) at relatively low catalyst/reaction temperatures (e.g., in the range from about 200° C. (392° C.) to about 400° C. (752° F.)). Representative catalysts for the pyrolysis of fluorine-containing compounds, and particularly perfluorinated compounds having these advantageous properties comprise a zirconia support having tungsten or sulfate deposited thereon (i.e., the catalysts comprise tungstated zirconia or sulfated zirconia).

When used in apparatuses for the treatment and/or monitoring of fluorine-containing compounds, the catalysts are resistant to particulates and other fouling/poisoning agents such as silica that are often present in gas emissions from semiconductor manufacturing, which generally serve as contaminated gas feeds to the processes and apparatuses described herein. Moreover, in such apparatuses, the catalysts exhibit short response (or line-out) and recovery times relative to conventional catalysts, in addition to high activity and stability as discussed above. These activity, stability, response, and recovery advantages are thought to be a function of the reduced adsorption of foulants, such as hydrogen fluoride, in addition to the reduced carry over of hydrogen fluoride into the gas effluent from the apparatus during a recovery phase when fluorine-containing compounds are not present in the feed gas stream to the apparatus.

Embodiments of the invention are therefore directed to processes for treating a gas stream comprising fluorine-containing compounds (e.g., perfluorinated compounds including perfluorocarbon compounds). The processes comprise contacting the gas stream with a catalyst comprising a tungstated zirconia or sulfated zirconia in the presence of water to pyrolyze at least a portion of the fluorine-containing compounds. These treating processes may be part of a monitoring process in which converted or pyrolyzed products (e.g., hydrogen fluoride) of the catalytic pyrolysis are detected in order to qualitatively determine the presence of fluorine-containing compounds in the gas stream or quantitatively determine the amount or concentration of these fluorine-containing compounds. Representative monitoring processes therefore further comprise detecting a pyrolysis product of the fluorine-containing compounds in a treated gas (or treated effluent) stream following contacting.

Further embodiments of the invention are directed to apparatuses for the pyrolysis of fluorine-containing compounds. The apparatuses comprise a reactor (e.g., a quartz tube) having an inlet for feeding a gas stream comprising fluorine-containing compounds to a catalyst contained in the reactor. The apparatuses further comprise an outlet for discharging a treated gas effluent following contacting of the gas stream with the catalyst in the reactor, and a heater for heating the catalyst.

Still further embodiments of the invention are directed to semiconductor manufacturing processes comprising exposing a semiconductor material to a reactive etching gas to generate a gas stream comprising fluorine-containing compounds and contacting the gas stream with a catalyst as described above in the presence of water to pyrolyze at least a portion of the fluorine-containing compounds. The contacting of the gas stream with a catalyst, or treating of the gas stream, may be carried out using an apparatus as described above to provide a treated gas effluent, resulting from contacting of the gas stream with a catalyst as described above. Particular embodiments, in which the gas stream is monitored as described above, can further comprise further comprise detecting a pyrolysis product (e.g., hydrogen fluoride) of the fluorine-containing compounds in a treated gas (or treated effluent) stream following contacting.

These and other embodiments, and their associated advantages, relating to the present invention are apparent from the following Detailed Description.

### BRIEF DESCRIPTION OF THE DRAWINGS

FIG. 1 is a graph showing the amount of the pyrolysis product, hydrogen fluoride (HF), detected over time in the gas effluent of a toxic gas monitor using a Chemcassette™ gas detection system (Honeywell, Inc., Morristown, N.J.). Separate curves show results obtained at different heater power levels (and catalyst bed temperatures), using a feed gas containing 9 vol ppm of perfluorocyclopentene (or octafluorocyclopentene, C₅H₈) that was passed through the catalyst bed at time T=0 seconds at a flow rate of about 40 cc/min and then replaced by pure nitrogen at the same flow rate at time T=2500 seconds. The catalyst used was tungstated zirconia having 12 wt-% tungsten and a surface area of the zirconia support of 51 m²/g.

FIG. 2 is a graph showing the amount of the pyrolysis product, hydrogen fluoride (HF), detected over time as described with respect to FIG. 1. The catalyst used, however, was tungstated zirconia having 7 wt-% tungsten and a surface area of the zirconia support of 51 m²/g.

FIG. 3 is a graph showing the amount of the pyrolysis product, hydrogen fluoride (HF), detected over time as described with respect to FIG. 1. The catalyst used, however, was sulfated zirconia having 1.5 wt-% sulfur and a surface area of the zirconia support of 51 m²/g.

FIG. 4 is a graph showing the amount of the pyrolysis product, hydrogen fluoride (HF), detected over time as described with respect to FIG. 1. The catalyst used, however, was sulfated zirconia having 12 wt-% tungsten and a surface area of the zirconia support of 17 m²/g.

FIG. 5 is a graph showing the relationship between perfluorocarbon conversion and heater power, using a toxic gas monitor as described with respect to FIG. 1. The two catalysts tested were both tungstated zirconia having 12 wt-% tungsten. The zirconia supports had surface areas of 17 m²/g and 51 m²/g.

### DETAILED DESCRIPTION

Aspects of the present invention are associated with the discovery of methods, catalysts, and apparatuses used in the treatment of gas streams comprising gaseous contaminants and/or the detection of these contaminants, particularly fluorine-containing compounds that are often used or generated in semiconductor material production methods. Representative fluorine-containing compounds are perfluorinated compounds composed entirely of fluorine and a second element selected from carbon, nitrogen, sulfur, and combinations thereof. Examples of perfluorinated compounds include nitrogentrifluoride (NF₃), sulfurhexafluoride (SF₆), as well as the perfluorocarbon compounds composed entirely of carbon and fluorine, including tetrafluoromethane (CF₄), hexafluoroethane (C₂F₆), octafluoropropane (C₃F₈), decafluorobutane (C₄F₁₀), octafluorocyclobutane (cyclo-C₄F₈), and octafluorocyclopentene (cyclo-C₅F₈). Other fluorine-containing compounds of interest in treatment and detection methods described herein are hydrofluorocarbon compounds containing at least one of each of the elements carbon, hydrogen and fluorine, such as, for example, trifluoromethane (CHF₃) and 1,1,1,2-tetrafluoroethane (C₂H₂F₄). Like perfluorocarbon compounds, hydrofluorocarbon compounds are thought to contribute to global warming. The fluorine-containing compounds, which are capable of being pyrolyzed according to the methods described herein, do not include hydrogen fluoride (HF), which is typically the product of pyrolysis or decomposition.

Fluorine-containing compounds also include chlorofluorocarbons (CFCs) and others that contain one or more halogens in addition to chlorine. Such compounds are widely used as foaming agents, refrigerants, fire extinguishing agents, fumigants, etc. Representative CFCs include CFC-113 (1,1,2-trichloro-1,2,2-trifluoroethane), CFC-11 (trichlorofluoromethane), CFC-12 (dichlorodifluoromethane). Representative feed gas streams therefore include those comprising both perfluorinated compounds, hydrofluorocarbon compounds, CFCs, and any combinations of these compounds. In general, the fluorine-containing compounds may be present in the contaminated feed gas stream in wide-ranging amounts, but typically this stream has a total fluoride content (as atomic F) from about 10 ppm to about 1% by volume, and often from about 10 ppm to about 5000 ppm by volume. In contrast, the treated gas effluent gas effluent after pyrolysis (e.g., after exiting a pyrolysis reactor or reaction zone containing the catalyst) generally contains less than about 10 ppm by volume of fluorine-containing compounds other than hydrogen fluoride.

Representative methods include contacting a gas stream as described above (e.g., obtained from a semiconductor manufacturing operation, for example, as an exhaust gas) with a catalyst comprising tungstated zirconia or sulfated zirconia that catalyzes pyrolysis (or catalytic hydrolysis or decomposition) of the fluorine-containing contaminant of the gas stream, such that at least a portion of fluorine-containing compounds are pyrolyzed or converted to hydrogen fluoride (HF) in addition to carbon monoxide (CO) and/or carbon dioxide (CO₂). The source of oxygen is normally water vapor that is generally, though not necessarily, present in at least a stoichiometric amount sufficient to convert the carbon content of the fluorine-containing compounds present to CO₂. Typically, water is present in an amount of at least twice the stoichiometric amount and often at least three times the stoichiometric amount. Although usually not necessary, a source of water vapor may be used to maintain a desired level of humidity in the contaminated feed gas prior to contacting the catalyst, for example at least about 50% relative humidity.

The methods are carried out under contacting conditions effective for converting generally at least about 80%, typically at least about 90%, and often at least about 95%, of fluoride in the contaminated gas stream to hydrogen fluoride. Depending on the desired conversion level and concentration of fluoride in the contaminated gas stream, the pyrolysis reaction temperature, or temperature of the catalyst during contacting, can be adjusted. Generally, an elevated catalyst bed temperature is used, for example in the range from about 200° C. (392° F.) to about 700° C. (1292° F.). Due to the high activity of the catalysts described herein for catalytic pyrolysis, however, lower catalyst bed temperatures, compared to those used with conventional catalysts (e.g., silica, alumina, or titania supported catalysts) under otherwise identical conditions, are often advantageously employed to achieve satisfactory conversion with a reduced energy requirement. Catalyst bed temperatures are therefore typically in the range from about 200° C. (392° F.) to about 500° C. (932° F.) and often from about 200° C. (392° F.) to about 350° C. (662° F.). The feed gas stream flow rate, in terms of micrograms of fluoride (as atomic F) processed per hour per gram of catalyst (μg F/hr·g cat), is generally from about 10 to about 10,000, typically from about 100 to about 5,000, and often from about 200 to about 2,500. A wide range of reaction pressures may be used for the pyrolysis of fluorine-containing compounds, but pressures near atmospheric, for example, from about 0 psig (0 barg) to about 145 psig (10 barg) are commonly chosen for convenience.

Treatment methods, as described herein, therefore effectively pyrolyze fluorine-containing compounds to HF. The HF in the gas effluent exiting the catalytic reactor may then be efficiently removed, for example, by scrubbing using a basic solution such as a hydroxide solution (e.g., sodium hydroxide, potassium hydroxide, ammonium hydroxide, etc.). The treatment methods may also be part of a monitoring or detection method that further involves detecting HF in the treated gas effluent. In a representative embodiment, the treated gas effluent, after the pyrolysis of fluorine-containing compounds in the feed gas, is analyzed for HF content by optical scanning to detect a color change upon subjecting the effluent to a chemically impregnated substrate such as paper. This detection/monitoring step, in which HF is reacted chemically to effect a color change, is exemplified by the Chemcassette™ gas detection system (Honeywell, Inc., Morristown, N.J.) for responsive and accurate monitoring of gas streams, even at very low contaminant concentrations.

As discussed above, aspects of the invention relate to the discovery of effective catalysts for the gas treating methods described herein that have a number of advantages over conventional catalysts, particularly with respect to their use in apparatuses that pyrolyze gas streams comprising fluorine-containing compounds. Such apparatuses may be used in the treatment of contaminated gases, for example emissions from semiconductor manufacturing facilities. In a preferred embodiment, apparatuses utilizing the tungstated or sulfated zirconia catalysts are used in the detection and/or monitoring of feed gases contaminated with fluorine-containing compounds. A representative apparatus is the MDA SPM™ Toxic Gas Monitor from Honeywell Analytics (Honeywell, Inc., Morristown, N.J.) that utilizes the Chemcassette™ gas detection system as described above. The catalysts described herein have been found to exhibit a combination of important benefits in such apparatuses, including an improved response to the detection of the fluorine-containing compounds, high pyrolysis activity that results in reduced utility or heater power requirements, and low carryover of the fluorine-containing compounds and pyrolysis reaction products after removal of fluorine-containing contaminants. Without being bound by theory, the responsiveness of the catalysts is thought to result from a shortened activation or equilibration period, upon being first contacted with contaminated gas stream. The low carryover is believed to result from reduced adsorption or affinity of feed and reaction components that remain to some extent in the catalyst bed and that are removed over time by purging with uncontaminated gas (e.g., pure nitrogen or air containing no fluorides).

Supports for the tungstated or sulfated zirconia catalysts may utilize a zirconium hydroxide precursor that is available, for example, from MEI of Flemington, N.J. Alternatively, the hydroxide may be prepared by hydrolyzing metal oxy-anion compounds, for example ZrOCl₂, ZrO(NO₃)₂, ZrO(OH)NO₃, ZrOSO₄, TiOCl₂ and the like. Zirconium alkoxides such as zirconyl acetate and zirconium propoxide may be used as well. Hydrolysis can be effected using a hydrolyzing agent such as ammonium hydroxide, sodium hydroxide, potassium hydroxide, sodium sulfate, (NH₄)₂HPO₄, and others. The metal oxy-anion component may in turn be prepared from available materials, for example, by treating ZrOCO₃ with nitric acid. The hydroxide as purchased or generated by hydrolysis is preferably is dried at a temperature from about 100° C. (212° F.) to about 300° C. (572° F.) to vaporize volatile compounds.

The support comprising zirconia or a precursor such as zirconium hydroxide can be used in powder form or in any desired shape such as a pill, cake, extrudate, granule, sphere, etc., in varying sizes. A representative zirconia powder has an average particle size from about 0.30 mm (50 mesh) to about 2.0 mm (10 mesh), and often from about 0.60 mm (30 mesh) to about 0.84 mm (20 mesh). Larger shapes, for example cylindrical extrudates having a diameter of about 3.2 mm (0.125 inches), may be formed by mixing the zirconia or precursor with a binder, although the catalyst may be made and successfully used without a binder, such that the support comprises substantially all (e.g., at least about 90%, typically at least about 95%, and often at least about 99%, by weight zirconia). The binder, when used, generally comprises from about 0.1% to about 50%, and typically from about 5% to about 20%, by weight of the finished catalyst. According to other embodiments, however, the support may comprise predominantly binder, for example in the range from 50% to about 99% binder, and often from about 75% to about 98% binder. Suitable binders include refractory inorganic oxides other than zirconia, with silica, alumina, silica-alumina, magnesia, zirconia, and mixtures thereof being representative. A preferred binder is alumina, with eta- and/or gamma-alumina being preferred. The zirconia or precursor and optional binder may be mixed along with a peptizing agent such as HCl, HNO₃, KOH, etc. to provide a homogeneous mixture that is formed into a desired shape according to known procedures. These include extrusion (e.g., using a screw extruder or extrusion press), spray drying, oil dropping, marumarizing, conical screw mixing, etc. The forming method determines how much water, if any, is added to the mixture. Thus, if extrusion is used, then the mixture should be in the form of a dough, whereas if spray drying or oil dropping is used, then sufficient water is required for slurry formation.

In the case of preparing tungstated zirconia catalysts, the support (which may be bound and/or formed as described above) is impregnated with a tungsten compound, generally by contacting the support, comprising zirconia or a zirconia precursor, with an impregnation solution of the compound. Suitable compounds include ammonium tungstate compounds such as ammonium metatungstate (AMT) and ammonium paratungstate (APT). Other compounds such as metatungstic acid, sodium tungstate, and others capable of forming tungsten oxide or tungstate ion upon calcining may be used. The concentration of the tungsten compound in such impregnation solutions generally ranges from about 0.1 M to about 5 M.

Methods for preparing sulfated zirconia include those described in “Catalysis Review,” SCI. ENG. 38 (3), 329-412 (1996). As discussed above, the methods can involve hydrolyzing a zirconium salt, such as ZrOCl₂ or ZrO(NO₃)₂ with aqueous ammonia to produce zirconium hydroxide as a precursor of the zirconia support. The zirconium hydroxide may then be treated with dilute sulfuric acid or (NH₄)₂SO₄ solution as an impregnation solution. Concentrations of sulfuric acid and ammonium sulfate impregnation solutions are generally in the range from about 0.01M to 10M, preferably from about 0.1M to about 5M. Sulfate precursors, or compounds capable of forming sulfate (e.g., after calcining) may also be used. Suitable precursors include hydrogen sulfide, sulfur dioxide, mercaptans, and sulfur- and halogen-containing compounds such as fluorosulfonic acid, sulfuryl chloride, thionyl chloride and other compounds capable of forming sulfate ions upon calcination.

Additional catalytic components, such as vanadium (e.g., as vanadate) may be dispersed on the support using the same impregnation solution containing sulfate and/or tungstate ions or using a different impregnation solution that is contacted with the support in a separate impregnation step. Further components may act as zirconia “dopants” to improve properties of the catalyst and/or support, including improved activity of catalysts having relatively low surface areas due to calcination at high temperatures, and/or improved surface area stability of the support, without necessarily impacting catalyst acidity to an appreciable extent. Dopants include the lanthanide-series elements, yttrium, or mixtures thereof. The lanthanide series elements include lanthanum, cerium, praseodymium, neodymium, promethium, samarium, europium, gadolinium, terbium, dysprosium, holmium, erbium, thulium, ytterbium and lutetium, with ytterbium, thulium, erbium, holmium, terbium, and mixtures thereof being preferred, and ytterbium being most preferred. Dopants and other components may in general be present in the catalyst in any suitable form such as the elemental metal, a compound such as the oxide, hydroxide, halide, oxyhalide, carbonate or nitrate or in chemical combination with one or more of the other ingredients of the catalyst. Oxide forms, intermetallics with platinum, sulfates, or forms in the zirconium lattice are preferred. Calcination generally yields the oxide form. The lanthanide element or yttrium, as dopants, can be incorporated into the catalyst in an amount generally from about 0.01% to about 10%, and typically from about 0.5% to about 5%, by weight of the finished catalyst. Incorporation of dopants and other further components may be carried out in any suitable manner, for example by coprecipitation, coextrusion with the zirconia support, or impregnation of the support either before, after, or simultaneously with tungstate and/or sulfate.

Whether or not one or more components in addition to tungstate or sulfate (e.g., the dopants described above) are incorporated into the catalyst composition, static or flowing conditions may be used for contacting between the impregnation solution and the support comprising zirconia or a zirconia precursor (e.g., zirconium hydroxide) to effect the desired degree of tungsten and/or sulfur impregnation. The impregnation solution contacting temperature is generally in the range from about 20° C. (68° F.) to about 200° C. (392° F.), and often from about 25° C. (77° F.) to about 150° C. (302° F.). The duration of contacting at this temperature (contacting time) is generally from about 1 minute to about 5 hours, and often from about 5 minutes to about 3 hours. The contacting time is inclusive of any subsequent drying step, in which the support and impregnation solution remain in contact at a temperature within these ranges. The impregnation conditions are selected to achieve a desired level of tungsten (as tungsten metal) or sulfur (as elemental sulfur), for example from about 5% to about 20% by weight in the case of tungsten and from about 1% to about 15% by weigh in the case of sulfur, in the resulting catalyst.

Specific impregnation methods include evaporative impregnation, in which the support is normally placed into a rotary evaporator which is equipped with a steam jacket. The impregnation solution with desired concentration(s) of tungstate and/or sulfate ions is added and the mixture cold rolled in the absence of steam for a time from about 10 to 60 minutes. Steam is then introduced to heat the mixture and evaporate the solvent over a period generally ranging from about 1 to about 4 hours to provide the tungstate- and/or sulfate-impregnated support. As an alternative to evaporative impregnation, which uses an excess of impregnation solution and evaporation of the solvent, a pore filling method may be used. In pore filling, the impregnation solution is used in an amount at least sufficient to occupy the pore volume of the support. Other methods of dispersing catalyticially active components onto the support comprising zirconia or a zirconia precursor include coprecipitation of the components or cogellation.

Following impregnation, the tungstate- and/or sulfate-impregnated support is then calcined, such that zirconium hydroxide in the support is converted substantially or completely to zirconia. Effective calcining procedures generally involve heating the support after impregnation to a temperature from about 300° C. (572° F.) to about 1000° C. (1832° F.), and often from about 400° C. (752° F.) to about 650° C. (1202° F.), for a time (or duration of heating of the support to this temperature) generally from about 1 hour to about 10 hours, and often from about 3 hours to about 9 hours. The heating is normally performed with a flow of oxygen-containing gas (e.g., air, oxygen, or oxygen-enriched air). Usually during the catalyst preparation procedure, drying zirconia support is carried out before the impregnation and/or drying of the impregnated, zirconia support is performed after the impregnation and before calcining. Typical conditions for either of these drying steps, if used, include a temperature from about 25° C. (77° F.) to about 250° C. (482° F.) and a time from about 0.5 hours to about 24 hours. Any or all of the drying and calcining steps may be performed under purge with a gas (e.g., air, oxygen, nitrogen, argon, etc. or mixture of gases), preferably at ambient or slightly elevated pressure.

In the resulting catalysts comprising tungstated or sulfated zirconia, the zirconia support generally has a surface area from about 1 m²/g to about 150 m²/g, and often from about 5 m²/g to about 100 m²/g. Also, the average pore diameter (or pore size) of the zirconia support is generally in the range from about 100 Å to about 500 Å, and often from about 150 Å to about 300 Å. Surface area and average pore diameter are measured according to the Brunauer, Emmett and Teller (BET) method based on nitrogen adsorption (ASTM D1993-03 (2008)). The total pore volume of the support is generally from about 0.01 cc/g to about 0.5 cc/g, and often from about 0.05 cc/g to about 0.30 cc/g. Especially good performance is obtained when the zirconia support is in the tetragonal phase, the monoclinic phase, or a combination of both of these phases.

Overall, aspects of the invention are directed to processes for pyrolyzing fluorine-containing compounds in contaminated gas streams by contacting them with a catalyst comprising tungstated zirconia or sulfated zirconia. Other aspects are directed to methods for detecting and/or monitoring fluorine-containing compounds by analyzing, either qualitatively or quantitatively, the pyrolysis reaction product, HF, in the gas effluent after pyrolysis (e.g., after exiting a pyrolysis reactor or reaction zone containing the catalyst). Further aspects are directed to apparatuses, including fluorine-containing compound monitoring and/or detecting apparatuses, that utilize the pyrolysis of fluorine-containing compounds, including perfluorinated compounds, according to methods described herein. In this regard, the catalysts described herein provide exceptional performance characteristics, as discussed above, when used in such detection and/or monitoring methods and apparatuses. In particular, important benefits are realized in terms of detection responsiveness, reduced HF carryover/desorption when the fluorine-containing compounds is no longer present (i.e., improved accuracy), and lower catalyst bed operating temperature (and consequently overall energy) requirements.

Yet further aspects of the invention are directed to the use of the pyrolysis methods in semiconductor manufacturing processes. In view of the present disclosure, it will be seen that several advantages may be achieved and other advantageous results may be obtained. Those having skill in the art will recognize the applicability of the methods disclosed herein to any of a number of pyrolysis methods, monitoring and detection processes, and apparatuses for carrying out these methods and processes. Those having skill in the art, with the knowledge gained from the present disclosure, will recognize that various changes could be made in the above processes without departing from the scope of the present disclosure.

The following examples are set forth as representative of the present invention. These examples are not to be construed as limiting the scope of the invention as other equivalent embodiments will be apparent in view of the present disclosure and appended claims.

### Example 1

Tungstated and sulfated zirconia catalyst samples were prepared using ammonium metatungstate and sulfuric acid impregnation solutions, respectively, as described above. After contacting the support and solution using a pore filling method, the impregnated supports were calcined in air for about 4 hours at about 625° C. (1157° F.) to provide catalysts having tungsten and sulfur contents, support surface areas, and other properties as described previously. A summary of pertinent information regarding these catalyst preparations is provided in the Table 1 below:

TABLE 1
Tungstated and Sulfated Zirconia Catalyst Preparations

| | Tungsten or | Support/Surface | |
|---|---|---|---|
| Catalyst | Sulfur Loading | Area | Particle Size |
| A | 12 wt-% W | 51 m²/g | 20-30 mesh |
| B | 7 wt-% W | 51 m²/g | 20-30 mesh |
| C | 1.5 wt-% S | 51 m²/g | 20-30 mesh |
| D | 12 wt-% W | 17 m²/g | 20-30 mesh |

The catalysts were tested for their performance in an MDA SPM™ Toxic Gas Monitor from Honeywell Analytics (Honeywell, Inc., Morristown, N.J.) utilizing a Chemcassette™ gas detection system for detecting the pyrolysis product hydrogen fluoride. The catalysts were loaded into the quartz tube reactor of the apparatus, which was equipped with a heater having variable power to attain a desired reactor/catalyst bed temperature for carrying out pyrolysis. A model feed stream containing 9 vol ppm of perfluorocyclopentene (or octafluorocyclopentene, C₅H₈) was passed through the catalyst bed at time T=0 seconds at a flow rate of about 40 cc/min. At time T=2500 seconds, the flow of gas containing the fluorine-containing compound was replaced with a flow of nitrogen.

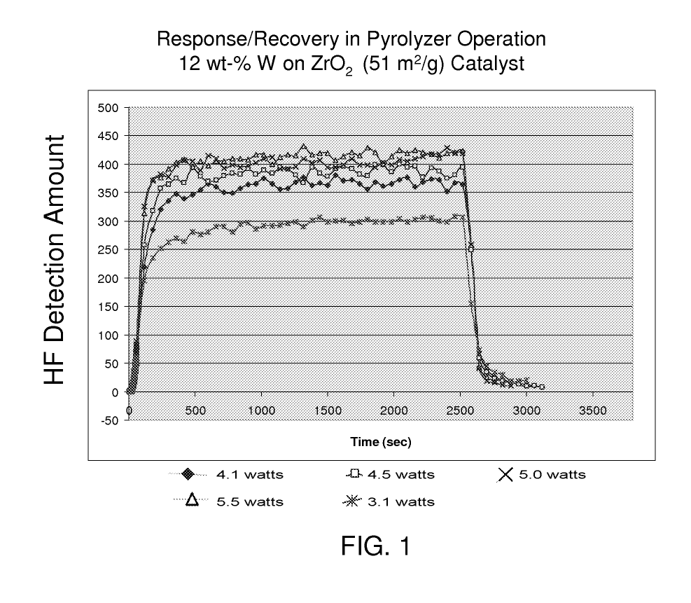

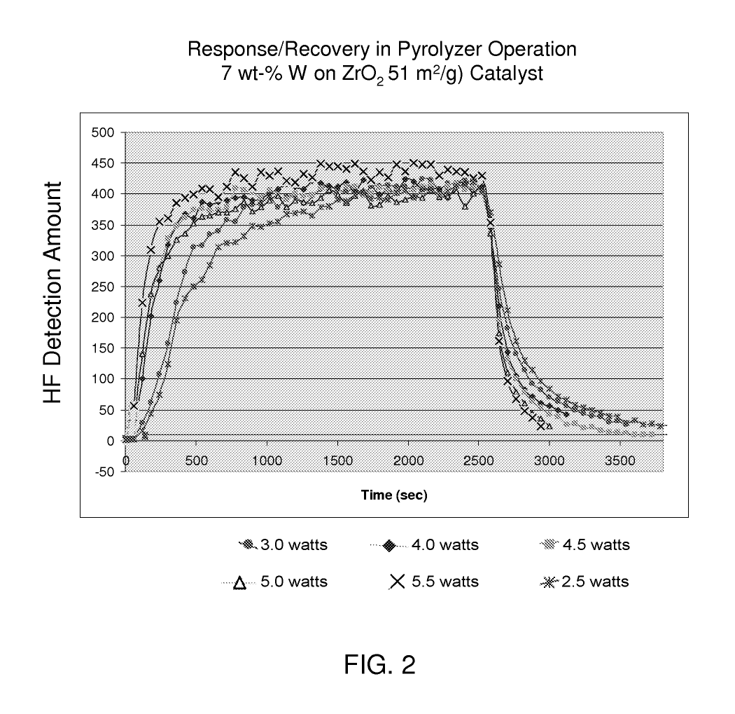

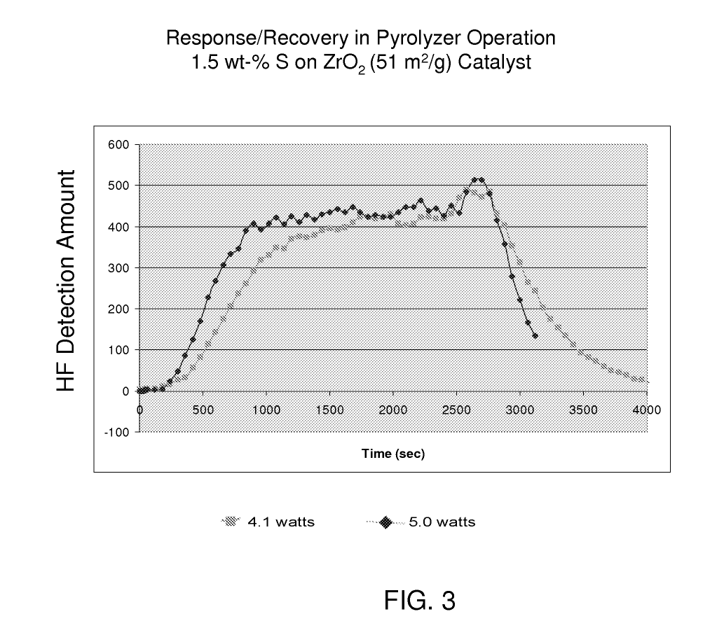

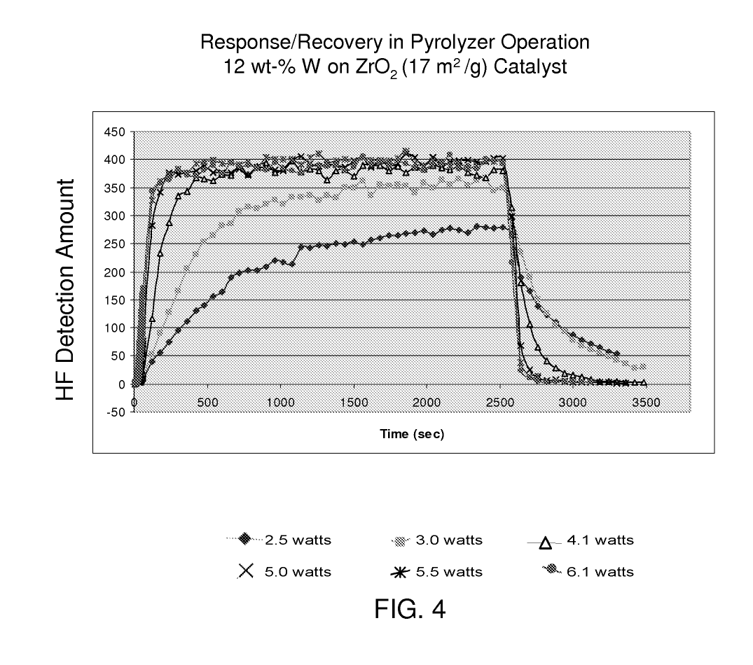

The graphs in FIGS. 1-4 show the relationships, for catalysts A-D, respectively, between the amount of the pyrolysis product, hydrogen fluoride (HF), detected over time in the gas effluent, at various heater power levels (and catalyst bed temperatures). A feed gas containing 9 vol ppm of perfluorocyclopentene (or octafluorocyclopentene, C₅H₈) was passed through the catalyst bed at time T=0 seconds at a flow rate of about 40 cc/min and then replaced with pure nitrogen at the same flow rate at time T=2500 seconds. The tests therefore demonstrated both the responsiveness and recovery exhibited by catalysts A, B, C, and D above, in addition to their activity. In particular, the results in FIGS. 1-4 show that these catalysts converted the fluorine-containing compound, very soon after its introduction, to HF (i.e., the catalysts all exhibited good responsiveness with little lag time between introduction of the contaminant and its detection in the gas effluent). Following removal of the contaminant, the detected amount of HF quickly decreased, due to a favorably small absorption of the fluorine-containing compound and/or latent desorption of its conversion product, HF (i.e., the catalysts all exhibited a short recovery time with little lag time between stopping flow of the contaminant and the accompanying, sharp decline in the amount of HF detected). Moreover, complete conversion (pyrolysis) of the perfluorocarbon was achieved at a relatively low heater power setting. The responsiveness, recovery, and activity of the tungstated and sulfated zirconia catalysts described herein were superior to the corresponding properties of conventional pyrolysis catalysts used in detection/monitoring apparatuses, including alumina, silica, and titania supported catalysts.

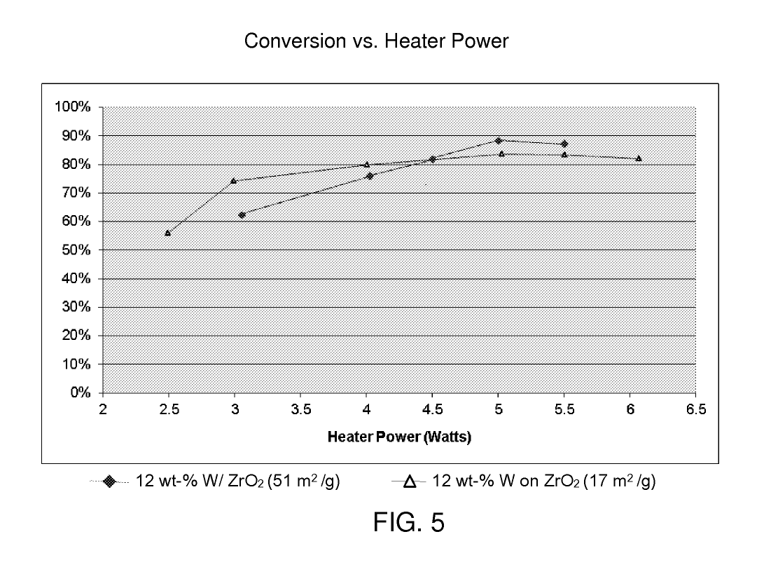

FIG. 5, generated from the data obtained from these experiments, further illustrate the high activity of catalysts described herein, as evidenced by the nearly complete conversion of the perfluorocarbon C₅H₈ at only moderate heater power settings. The two curves show the performance of catalysts A and D above, having 12 wt-% tungsten on zirconia supports with surface areas of 17 m²/g and 51 m²/g, respectively.

1. A method for treating a gas stream comprising fluorine-containing compounds, the process comprising contacting the gas stream with a catalyst comprising tungstated zirconia or sulfated zirconia in the presence of water to pyrolyze at least a portion of the fluorine-containing compounds.

2. The method of claim 1, wherein the fluorine-containing compounds comprise perfluorinated compounds.

3. The method of claim 2, wherein the perfluorinated compounds include perfluorocarbon compounds.

4. The method of claim 3, wherein the perfluorinated compounds include a compound selected from the group consisting of nitrogen trifluoride, sulfur hexafluoride, tetrafluoromethane, hexafluoroethane, octafluoropropane, octafluorocyclopentene, decafluorobutane, and mixtures thereof.

5. The method of claim 3, wherein the fluorine-containing compounds comprise both perfluorinated compounds and hydrofluorocarbon compounds.

6. The method of claim 1, wherein the gas stream has a fluoride content from about 10 ppm to about 5000 ppm by volume.

7. The method of claim 1, wherein the contacting with the catalyst converts at least about 80% of fluorine in the fluorine-containing compounds to hydrogen fluoride.

8. The method of claim 1, wherein the catalyst comprises a zirconia support having a BET surface area from about 1 m²/g to about 150 m²/g.

9. The method of claim 1, wherein the catalyst comprises a zirconia support having zirconia in a tetragonal phase, a monoclinic phase, or a combination of both phases.

10. The method of claim 1, wherein the catalyst comprises tungstated zirconia.

11. The method of claim 10, wherein the tungstated zirconia comprises tungsten in an amount from about 5% to about 20% by weight.

12. The method of claim 1, wherein the catalyst comprises sulfated zirconia.

13. The method of 12, wherein the sulfated zirconia comprises sulfur in an amount from about 1% to about 15% by weight.

14. The method of claim 1, wherein the contacting is carried out at a temperature in the range from about 200° C. (392° F.) to about 700° C. (1292° F.).

15. The method of claim 1, wherein the water is present in at least a stoichiometric amount sufficient to pyrolyze all fluorine-containing compounds in the gas stream to hydrogen fluoride.

16. An apparatus for the pyrolysis of fluorine-containing compounds, the apparatus comprising:
(a) a reactor having (i) an inlet for feeding a gas stream comprising fluorine-containing compounds to a catalyst contained in the reactor and (ii) an outlet for discharging a treated effluent stream following contacting of the gas effluent with the catalyst in the reactor, and
(b) a heater for heating the catalyst,
wherein the catalyst comprises tungstated zirconia or sulfated zirconia.

17. The apparatus of claim 16, wherein the reactor comprises a quartz tube.

18. A semiconductor manufacturing process comprising:
(a) exposing a semiconductor material to a reactive etching gas to generate a gas stream comprising fluorine-containing compounds, and
(b) contacting the gas stream with a catalyst comprising tungstated zirconia or sulfated zirconia in the presence of water to pyrolyze at least a portion of the fluorine-containing compounds.

19. A semiconductor manufacturing process comprising:
(a) exposing a semiconductor material to a reactive etching gas to generate a gas stream comprising fluorine-containing compounds, and
(b) treating the gas stream with the apparatus of claim 16 to provide a treated gas effluent, resulting from contacting of the gas stream with the catalyst comprising tungstated zirconia or sulfated zirconia.

20. The process of claim 19, wherein the treated gas effluent contains less than 10 ppm by volume of fluorine-containing compounds other than hydrogen fluoride.
